(19) United States
(12) Patent Application Publication
(10) Pub. No.: US 2015/0340858 A1
(43) Pub. Date: Nov. 26, 2015

(54) SYSTEM AND METHOD FOR QUENCH PROTECTION OF A CRYO-FREE SUPER CONDUCTING MAGNET

(71) Applicant: KONINKLIJKE PHILIPS N.V., Eindhoven (NL)

(72) Inventor: Alexander AKHMETOV, Schenectady, NY (US)

(21) Appl. No.: 14/653,281

(22) PCT Filed: Dec. 18, 2013
(86) PCT No.: PCT/IB2013/061073

§ 371 Date: Jun. 18, 2015

Related U.S. Application Data
(60) Provisional application No. 61/746,409, filed on Dec. 27, 2012.

(51) Int. Cl. H02H 7/00; G01R 33/38; G01R 33/3815

(52) U.S. Cl. CPC H02H 7/001; G01R 33/3815; G01R 33/3804

(57) ABSTRACT

A system including a first sealed housing with a first pressure and a second sealed housing with a second pressure. The first pressure is higher than the second pressure. The first sealed housing contains a predetermined gas and the second sealed housing contains a superconducting magnet. A sensor within the second housing monitors a voltage of parts of the magnet. When a processor determines a quenching event as a function of the monitored voltage, the processor actuates a valve that sealably connects the first and second housings. When the valve is in a first position, the first and second housings are sealed off from each other. When the valve is in a second position, the predetermined gas flows from the first housing into the second housing until a third pressure within the second housing is reached. The system can be used for protecting a cryo-free superconducting magnet.

### CROSS REFERENCE TO PRIOR APPLICATION

This application claims the benefit of U.S. Provisional Patent Application No. 61/746,409, filed Dec. 27, 2012 which is hereby incorporated by reference herein.

The present disclosure generally relates to a superconducting Nuclear Magnetic Resonance (NMR) or Magnetic Resonance Imaging (MRI) magnet operating in a cryo-free environment, and, in particular, to a system, apparatus, arrangement, and method for preventing a voltage breakdown during a quenching event.

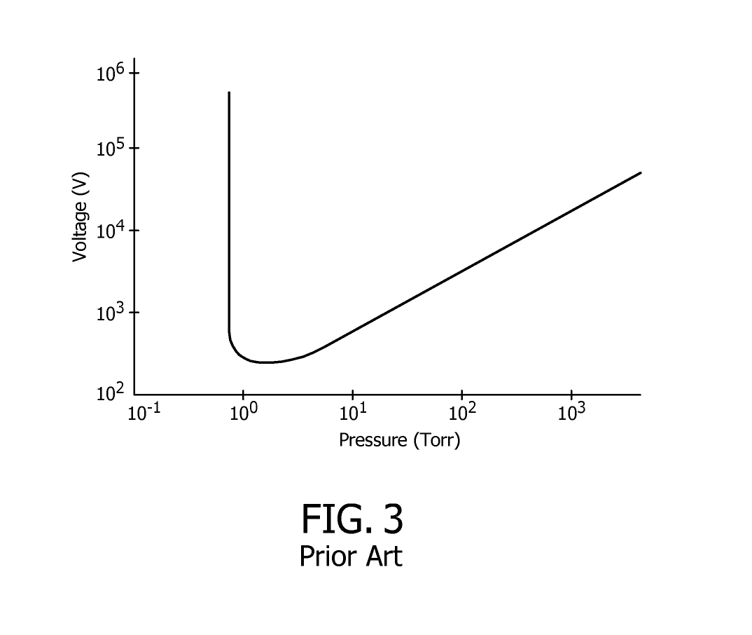

Electrical breakdown of superconducting magnets operating in Cryo-free environment presents a formidable problem. The voltage which develops between the parts of the magnet during a quench can reach thousands or tens of thousands volts. If a magnet is properly produced, the quench voltage is less than the breakdown voltage. In Cryo-free conditions the breakdown voltage is defined by the Paschen curve shown in FIG. 3, which relates the breakdown voltage to the residual gas pressure in the volume containing the magnet whose parts are at a specific distance from each other. With the pressure decrease, the breakdown voltage initially decreases as well, then reaches its minimum, and, finally, begins to increase again. It is common practice to pump the inner volume of a Cryo-free magnet to a very low pressure, i.e. to the point where the breakdown voltage is high. The relationship between the pressure inside of a cryostat and the magnet voltage is defined by the Paschen curve shown in FIG. 3, which displays the Paschen curve for a magnet whose parts are at a fixed distance from each other. The Paschen curve represents the breakdown voltage at a specific pressure. Any point below the curve is characterized as safe operation condition, whereas any point above the curve results in damage to the magnet.

During a quench, a magnet can be damaged by high voltage and/or high temperature developed locally. One of the problems that results from the quench is series of thermal events. Parts of the magnet or magnet components can become hot and, consequently, can disgorge absorbed gases.

Also, the chemical decomposition of complex magnet materials such as epoxy, insulation, unwashed flux etc may lead to gas production, causing further vacuum deterioration. Resulting contamination of the vacuum might lead to the uncontrolled increase of the residual pressure in the originally evacuated volume, which, in turn, would result in the quench voltage exceeding the magnet's breakdown voltage. This ultimately results in the destruction of the magnet. There are various accepted methods of counteracting the high voltage problems resulting from a quench in a cryo-free magnet. For instance, one method requires the application of additional layers of insulation over any exposed or insufficiently insulated metallic surfaces. Another method involves keeping the magnet current density low enough so that the voltage developed during the quench is also low. Another method requires protecting the magnet with shunts, which can be made of electrical resistors or diodes or both. These methods can be prohibitively expensive in mass production. Additionally, in MRI magnets, the diode-resistor shunt solution compromises the stray field during the quench and can result in magnetic field blooming.

Exemplary embodiments of the present disclosure can provide, for example, systems, apparatus, arrangements, and methods for protecting a magnet during the quenching event. Aspects of the present disclosure can provide added protection during the quenching event to avoid potential damage to the magnet.

According to an exemplary embodiment of the present invention, a system for protecting a magnet during a quenching event can be provided. The system can include (i) a first sealed housing having a first pressure and containing a predetermined gas; (ii) a second sealed housing having a second pressure, the first pressure being higher than the second pressure; (iii) a magnet disposed within the second housing; (iv) a sensing device monitoring a voltage of parts of the magnet; (v) a processor configured to determine a quenching event as a function of the voltage; (vi) a system of conventional magnet protection; and (vii) a valve sealably connecting the first and second housing, the valve being switchable between a first position and a second position. When the valve is in the first position, the first and second housings are sealed from each other to maintain the first pressure and the second pressure respectively. When the valve is in the second position, the first and second housings are sealably connected to each other allowing the gas to flow form the first housing to the second housing. The valve switches from the first position to the second position when the quenching event is detected so that the gas flows from the first housing into the second housing until a third pressure within the second housing is reached. The third pressure is determined as a function of the first pressure, the second pressure, parameters of the first and second housings, and parameters of the quenching event.

According to a further exemplary embodiment of the present invention, a method for protecting a magnet during a quenching event can be provided. The method can include monitoring, using a sensing device, a voltage of parts of a superconducting magnet of a system. The system further includes a first sealed housing, a second sealed housing and a valve. The first housing contains a predetermined gas and has a first pressure within. The second sealed housing contains the magnet and has a second pressure within. The first pressure is higher than the second pressure. The valve sealably connects the first and second housings and is switchable between a first position and a second position. The method also includes determining, by a processor, a quenching event as a function of the voltage; and, upon detecting the quenching event, switching the valve from the first position to the second position so that the gas flows from the first housing into the second housing until a third pressure within the second housing is reached. The third pressure is determined as a function of the first pressure, the second pressure, parameters of the first and second housings, and, to a lesser degree, parameters of the quenching event. When the valve is in the first position, the first and second housings are sealed from each other to maintain the first pressure and the second pressure respectively. When the valve is in the second position, the first and second housings are sealably connected to each other allowing the gas to flow from the first housing to the second housing.

The present invention is explained in greater detail in the following exemplary embodiments and with reference to the figures, where identical or similar elements are partly indicated by the same reference numerals, and the features of various exemplary embodiments being combinable. In the drawings:

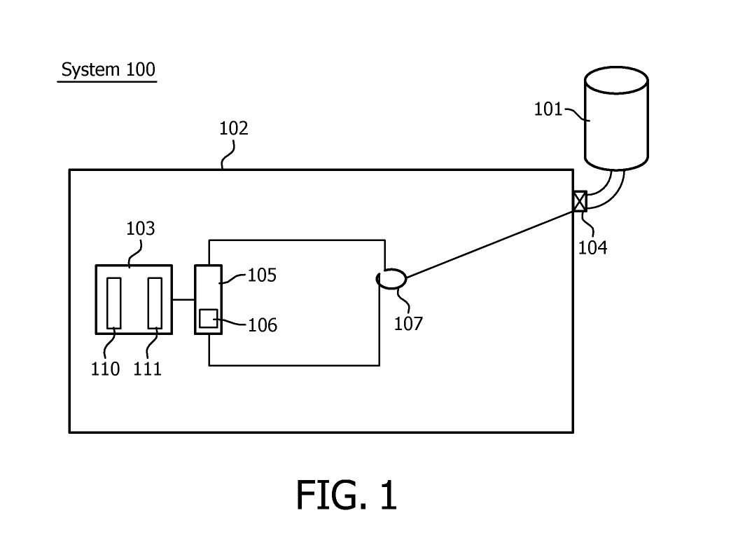

FIG. 1 shows a diagram of an exemplary system according to an exemplary embodiment of the present invention.

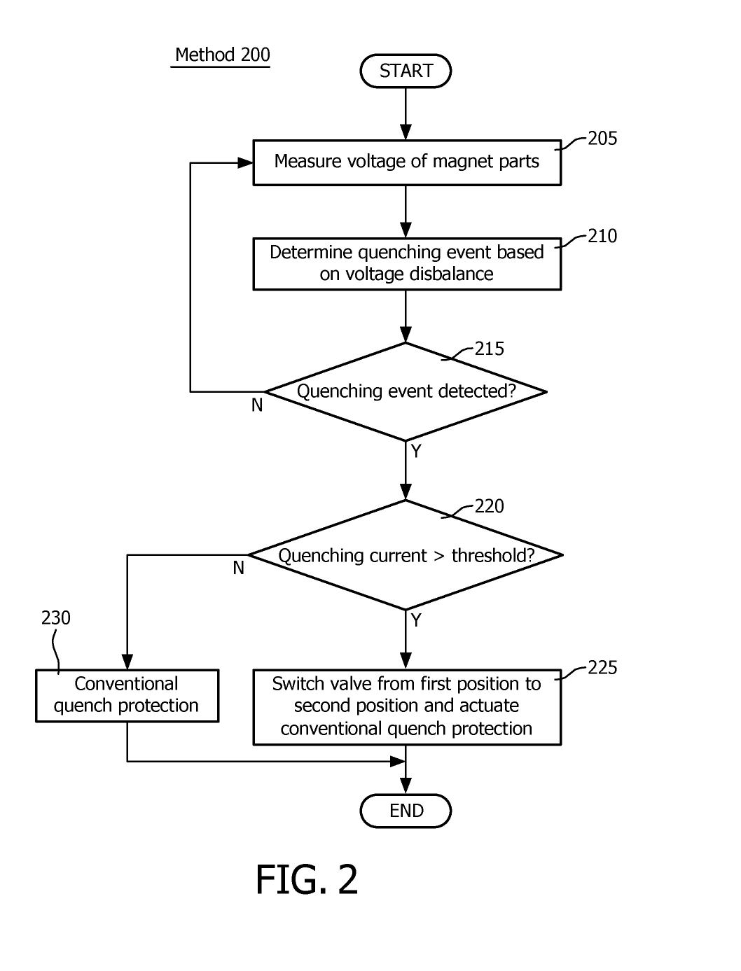

FIG. 2 shows an exemplary method for protecting a cryo-free superconducting magnet during a quenching event according to an exemplary embodiment of the present invention.

FIG. 3 shows an example of a Paschen curve according to the known relationship of a breakdown voltage to pressure in a magnet having a fixed distance between its electrodes.

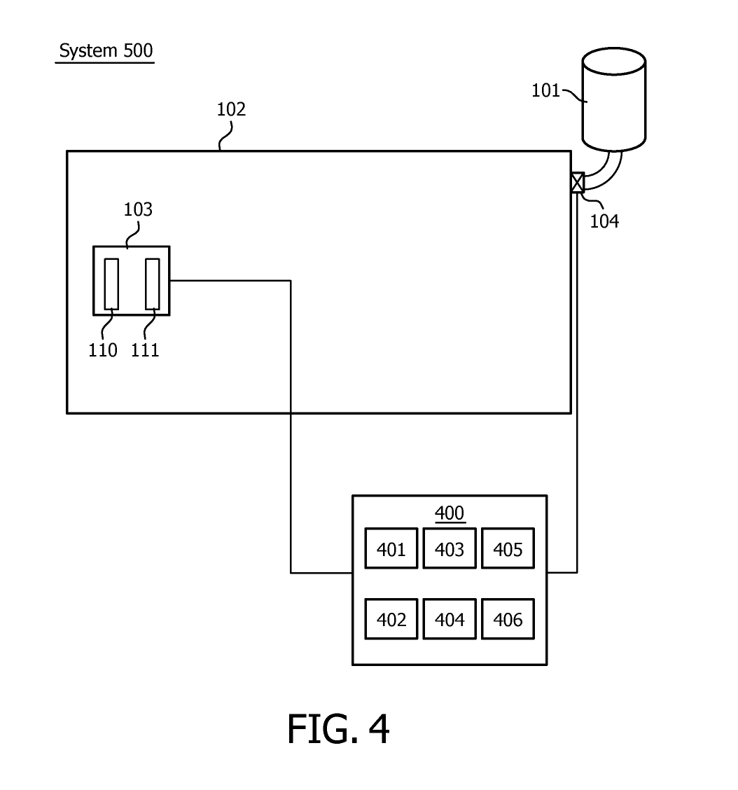

FIG. 4 shows a further exemplary embodiment of an exemplary system according to an exemplary embodiment of the present invention.

The exemplary embodiments may be further understood with reference to the following description and the appended drawings, wherein like elements are referred to with the same reference numerals. The exemplary embodiments generally relate to a method and system for protecting a cryo-free superconducting magnet during a quenching event.

FIG. 1 shows an exemplary system 100 for protecting a superconducting magnet 103 (e.g., a cryo-free superconducting magnet) during the quenching event according to an exemplary embodiment of the present invention. The system 100 may include a first sealed housing 101 and a second sealed housing 102 (e.g., a cryostat). The second sealed housing 102 contains the magnet 103 and a sensor 105. The system 100 may also include an amplifying device 107 (e.g., relay coil, amplifier, etc.) to amplify signals from the sensor 105.

The first sealed housing 101 is connected to the second sealed housing 102 via a valve 104. The first sealed housing 101 contains a predetermined gas at a first pressure. It should be noted that the first sealed housing 101 may contain any predetermined gas such as, for example, Helium, Neon, Argon, Nitrogen, etc. According to an exemplary embodiment, Helium gas is used because of its preferred lower gas-to-liquid transition temperature. In one exemplary embodiment, the first sealed housing 101 may be removably connected to the second sealed housing 102 using any conventional coupling. For example, the first sealed housing 101 can be a tank which is coupled to the valve 104 via a conventional threaded connection. In another exemplary embodiment, the first sealed housing 101 may instead be permanently coupled to the valve 104. In such an embodiment, the first sealed housing 101 will preferably include an arrangement for refilling the first sealed housing 101 with the predetermined gas once the gas has been depleted.

During normal operation, the second sealed housing 102 has a second pressure that is significantly less than the first pressure. Preferably, the second pressure corresponds to a vacuum pressure. In addition, during normal operation, the temperature (T1) inside of the second sealed housing 102 may be between 2 K to 10 K in the case of low temperature superconductors (e.g., Nb—Ti or Nb3Sn) or may also be significantly higher (e.g., up to 70 K) in case of high temperature superconductors (e.g., Y—Ba—Cu—O).

The magnet 103 is disposed inside of the second sealed housing 102 and includes at least a first magnet part 110 and a second magnet part 111. It should be noted, however, that the magnet 103 can include any number of parts necessary to properly operate. When the magnet 103 is charged, the first and second magnet parts 110, 111 develop an inductive voltage. When the magnet 103 is designed, the ratio of the voltage developed in the first magnet part 110 to the voltage developed in the second magnet part 111 is known. During normal operation, the ratio of the voltage of the first and second magnet parts 110, 111 should be substantially the same as this known ratio. During a quenching event, the ratio of the voltage of the first and second magnet parts 110, 111 deviates from the known ratio. This occurs because at least a portion of the magnet 103 becomes normal (i.e. loses its superconductivity) resulting in the resistive voltage. At the later stage of the quenching event, a resistive voltage of the magnet 103 rapidly increases. This may cause heat generation and, consequently, an increase in the temperature of the magnet 103. Simultaneously, the vacuum in the sealed housing 102 deteriorates due to release of gases trapped or produced in the heated parts of the magnet.

The sensor 105 is configured to monitor the voltage of the magnet parts 110, 111. The sensor 105 is communicatively coupled to the amplifying device 107. It should be noted that the amplifying device 107 does not need to be disposed inside of the second sealed housing 102. A processor 106 may be communicatively coupled to the sensor 105. It should be noted that the configuration shown in FIG. 1 is illustrative and that the processor 106 may alternatively be located outside of the housing 102 and communicate with the sensor 105. The processor 106 configured to analyze the measurements of the sensor 105 and determine whether a quenching event has begun. Upon detecting the quenching event, the processor 106 engages the amplifying device 107, which amplifies the signal and operates a conventional magnet protection scheme (not shown). It also controls the position of the valve 104. In a further embodiment, the sensor 105, the processor 106, and the amplifying device 107 can be replaced with a computing device that monitors the voltage of the magnet parts 110, 111 and controls the conventional protection circuit and the position of the valve 104. It should be noted that the sensor 105 and the amplifying device 107 may be replaced by any device capable of monitoring voltage and sending a signal to the valve 104 to control its position together with the conventional protection circuit. For example, a computing device 400 (see FIG. 4) described below may be used to monitor the voltage of first and second magnet parts 110, 111 and control the valve 104 together with the conventional protection circuit.

The valve 104 is switchable between a first position (e.g., closed position) and a second position (e.g., open position). It should be noted that the valve 104 may include any type of valve suitable for allowing the gas to enter the second sealed housing 102. For example, in extreme cases where a rapid burst of the gas is necessary, a burst disk may be used. Such a disk would need to be replaced after every quenching event in which the disk was actuated. During the normal operation of the magnet 103, the valve 104 remains in the first position, thereby sealing the first sealing housing 101 and the second sealed housing 102 from each other. Upon detecting the quenching event, the sensor 105 sends a signal to the amplifying device 107 and the conventional protection circuit. The sensor 107 then amplifies the signal and sends it to the valve 104. This results in the actuation of the valve 104 so that the valve 104 switches from the first position to the second position. In the second position, the predetermined gas is allowed to flow from the first sealed housing 101 into the second sealed housing 102 until a third pressure is developed in the second sealed housing 102. Since the first pressure inside of the first sealed housing 101 is necessarily higher than the second pressure inside of the second sealed housing 102, the gas moves from the first sealed housing 101 to the second sealed housing 102 autonomously. However, it should be noted that a pump (not shown) may optionally be used to expedite the transfer of the gas. For example, an airbag-like pump may be used in extreme cases where the gas must be pumped into the second sealed housing 102 in an extremely short period of time. Such an airbag-like pump may also be used together with the burst disk disclosed above. The valve 104 switches back to the first position when the magnet 103 is reset for subsequent ramps.

The highest voltage and temperature that can be reached by the magnet 103 during a quenching event (i.e. quench voltage) are calculated when the magnet 103 is designed. Also, the breakdown voltage for a specific gas pressure (See FIG. 3) is already known. Therefore, the volume of gas needed to raise the pressure in the second sealed housing 102 to the third pressure, at which the magnet 103 will not be damaged from the quenching event (i.e. a point below the Paschen curve), will also be known. It should be noted, however, that, depending on the quench current, the magnet 103 does not always reach the maximum quench voltage and temperature during every quenching event. For example, if the quench current is significantly less than the maximum possible current, it may not be necessary to switch the valve 104 from the first position to the second position. This is possible because the quench voltage and temperature are low enough that magnet 103 should not be damaged. Therefore, the system 100 may also include an apparatus (not shown) that evaluates the quench current before the valve 104 is actuated.

FIG. 2 shows a method 200 for protecting the magnet 103 according to a preferred exemplary embodiment of the present invention. In step 205, the voltage of the magnet parts 110, 111 is monitored. As previously explained, this monitoring is performed by the sensor 105. However, any apparatus, inside or outside of the second sealed housing 102, capable of monitoring voltage may alternatively be used. For example, a voltmeter or a computing device (as shown in FIG. 4) may be used to monitor the voltage of the first and second magnet parts 110, 111.

At step 210, the determination of the quenching event based on the voltage disbalance (i.e. the deviation from the known voltage ratio) between the magnet parts 110, 111 is performed. When the first and second magnet parts 110, 111 are no longer operating at the known voltage ratio, a voltage disbalance is detected. This voltage disbalance indicates that the quenching event has started. The measurements of the sensor 105 may be analyzed by the processor 106 to make this determination. The effects of the quench, if not prevented, may include a local increase of temperature and voltage, increase of the second pressure in the second sealed housing 102, and damage to the magnet 103.

At step 215, it is determined whether or not a quenching event has been detected. If a quenching event has not been detected (i.e. the voltage ratio between the first and second magnet parts 110, 111 does not change), the method 200 returns to step 205 and the voltage of the first and second magnet parts 110, 111 continued to be compared. If, however, a quenching event is detected at step 215, the method continues to step 220, where the quench current is evaluated. If the quench current is below a predetermined threshold value, the method continues to step 230, where the conventional quench protection techniques (not discussed here) are utilized. However, if the quench current exceeds the predetermined threshold value, the method continues to step 225, where the valve 104 is actuated in addition to the actuation of the conventional protection circuit.

At step 225, the valve 104 is switched from the first position to the second position. This results in the rapid flow of the predetermined gas from the first sealed housing 101 to the second sealed housing 102. As a result, the second pressure inside of the second sealed housing 102 quickly increases to a higher third pressure. As previously explained, the highest possible quench voltage of the magnet 103 is known. So, the necessary volume of gas needed to achieve the third pressure is also known. Therefore, the required volume of gas enters the second sealed housing 102 increasing the breakdown voltage of the magnet 103 so that the breakdown voltage corresponding to the third pressure is greater than the highest possible quench voltage.

FIG. 4 shows a system 500 according to a further exemplary embodiment of the present invention. System 500 substantially corresponds to the system 100 of FIG. 1. However, in system 500, a measuring device (e.g., a voltmeter) 401 replaces the sensor 105 and a computation device (e.g., a computer) 405 replaces the processor 106. A data acquisition system 403 is configured to transfer data from the measuring device 401 to the computation device 405.

The computation device 405 includes a unit 402 which serves as a user interface. The output signal from the computation device 405 is directed to an amplifier 404. Subsequently, the signal leaves the amplifier 404 and is received at an execution device 406, which operates a conventional protection circuit (not shown) and the valve 104.

It should be noted that any type of measuring device 401 may be used with the computational device 405 to perform the method of the present invention. Also, different kinds of amplifiers 404 and execution devices 406, including mechanical, electrical, and/or thermal devices may be used. In certain embodiments, the amplifier 404 and execution device 406 may be combined in one unit (not shown).

While the present invention has been shown and described with reference to particular exemplary embodiments, it will be understood by those skilled in the art that present invention is not limited thereto, but that various changes in form and details, including the combination of various features and embodiments, may be made therein without departing from the spirit and scope of the invention.

Those skilled in the art will understand that the above-described exemplary embodiments may be implemented in any number of manners, including, as a separate software module, as a combination of hardware and software, etc. For example, the acquisition system 403 may be a program containing lines of code that, when compiled, may be executed on a processor.

It is noted that the claims may include reference signs/numerals in accordance with PCT Rule 6.2(b). However, the present claims should not be considered to be limited to the exemplary embodiments corresponding to the reference signs/numerals.

It will be apparent to those skilled in the art that various modifications may be made to the disclosed exemplary embodiments and methods and alternatives without departing from the spirit or scope of the disclosure. Thus, it is intended that the present disclosure cover modifications and variations provided that they come within the scope of the appended claims and their equivalents.

1. A system, comprising:
a first sealed housing containing a predetermined gas at a first pressure;
a second sealed housing with its contents having a second pressure, the first pressure being higher than the second pressure;
a superconducting magnet operating in a cryo-free environment and disposed within the second housing;
a sensing device monitoring a voltage of parts of the magnet;
a processor configured to determine a quenching event as a function of the voltage; and
a valve sealably connecting the first and second housing, the valve being switchable between a first position and a second position,
wherein when the valve is in the first position, the first and second housings are sealed from each other to maintain the first pressure and the second pressure respectively,
wherein when the valve is in the second position, the first and second housings are sealably connected to each other to allow the gas to flow from the first housing to the second housing,
wherein, when the quenching event is detected, the valve is switched from the first position to the second position so that the gas flows from the first housing into the second housing until a third pressure within the second housing is reached, the third pressure being determined as a function of the first pressure, the second pressure, parameters of the first and second housings, and parameters of the quenching event.

2. The system of claim 1, wherein when a voltage ratio of the parts of the magnet exceeds a predetermined threshold, the valve switches from the first position to the second position, and
further wherein the switching of the valve supplements an engagement of an additional magnet protection system.

3. (canceled)

4. The system of claim 1, wherein the superconducting magnet is one of a magnetic resonance imaging (MRI) magnet and a nuclear magnetic resonance (NMR) magnet.

5. (canceled)

6. The system of claim 4, wherein the predetermined gas is helium.

7. The system of claim 1, wherein the valve switches from the second position to the first position when the magnet is reset for subsequent quenching events.

8. The system of claim 1, wherein, when the valve is in the second position, a predetermined volume of gas is allowed to enter the first sealed housing.

9. The system of claim 1, wherein the second pressure corresponds to a vacuum pressure.

10. The system of claim 1, wherein at the third pressure, a breakdown voltage is greater than a maximum quench voltage.

11. The system of claim 1, wherein the valve is disposable and the gas flow is assisted by a pump.

12. A method, comprising:
monitoring, using a sensing device, a voltage of parts of a superconducting magnet operating in a cryo-free environment of a system; the system further including a first sealed housing, a second sealed housing, and a valve, the first housing containing a predetermined gas and having a first pressure, the second sealed housing containing the magnet and having a second pressure, the first pressure being higher than the second pressure, the valve sealably connecting the first and second housings and being switchable between a first position and a second position;
determining, by a processor, a quenching event as a function of the voltage; and
upon detecting the quenching event, switching from the first position to the second position so that the gas flows from the first housing into the second housing until a third pressure within the second housing is reached, the third pressure being determined as a function of the first pressure, the second pressure, parameters of the first and second housings, and parameters of the quenching event;
wherein when the valve is in the first position, the first and second housings are sealed from each other to maintain the first pressure and the second pressure respectively, and
wherein when the valve is in the second position, the first and second housings are sealably connected to each other to allow the flow of the gas from the first housing into the second housing.

13. The method of claim 12, further comprising:
when the magnet is reset for subsequent ramps, switching from the second position to the first position.

14. The method of claim 12, wherein the valve switches from the first position to the second position when a voltage ratio of the parts of the magnet exceeds a predetermined threshold.

15. The method of claim 12, wherein the magnet is a superconducting magnet operating in a cryo-free environment, the superconducting magnet being one of a magnetic resonance imaging (MRI) magnet and a nuclear magnetic resonance (NMR) magnet, and further wherein the predetermined gas is helium.

16-17. (canceled)

18. The method of claim 12, wherein, when the valve is switched from the first position to the second position, a predetermined volume of gas is allowed to enter the first sealed housing.

19. The method of claim 12, wherein the second pressure corresponds to a vacuum pressure, and further wherein, at the third pressure, a breakdown voltage is greater than a maximum quench voltage.

20. (canceled)
